(19) United States
(12) Patent Application Publication
(10) Pub. No.: US 2012/0090879 A1
(43) Pub. Date: Apr. 19, 2012

(54) FLEXIBLE PRINT CIRCUIT BENDING METHOD FOR CONNECTING IN A PHONE AND FLEXIBLE PRINT

(75) Inventors: CHIN-HSU LAI, Taipei County (TW); Chih-Ming Chang, Taipei County (TW); Szu-Wei Wang, Taipei County (TW)

(73) Assignee: ALTEK CORPORATION, Hsinchu (TW)

(21) Appl. No.: 12/987,537

(22) Filed: Jan. 10, 2011

(30) Foreign Application Priority Data
Oct. 15, 2010 (TW) 099135349

(51) Int. Cl. H05K 1/00; H05K 13/04

(52) U.S. Cl. 174/254; 29/825

(57) ABSTRACT

The present invention discloses a flexible print circuit board bending method for connecting in a smart phone and a flexible print circuit board thereof. In the method, several portions of a flexible print circuit board is bend to suit multiple electronic units mounted on the front or rear casing of a smart phone. Consequently, there is only one surface of the flexible print circuit board needs to be processed to dispose connecting points, so cost of manufacturing the smart phone could be decreased. Besides, bending the flexible print circuit board to suit the electronic units could avoid space waste in the smart phone, such that helps to efficiently narrow down the scale of the smart phone.

### FIELD

The exemplary embodiment(s) of the present invention relates to a field of a flexible print circuit board bending method for connecting in a cell phone and a flexible print circuit board thereof. More specifically, the exemplary embodiment(s) of the present invention relates to an assembling way and that could decrease the space occupied by the devices in the cell phone.

### BACKGROUND

With the advances in the technology, the invented cell phone makes lots of conveniences to the modern people. The cell phone not only has the functions of communicating with other people or sending messages at any time, but also has lots of advantages such as easy to carry, and thus the cell phones become an indispensable and important communication tool. With the progress of the nowadays technology, the functions of the cell phones are updated and advanced daily and daily, and cell phones having a processor that increases the computing ability are becoming a trend. However, the functions such as tacking pictures or recording of this kind of cell phone are much more than the conventional cell phone, and thus the electronic devices of this kind of cell phone are more complicated than the conventional cell phone.

In the nowadays technology, a flexible print circuit board (FPC) is used as a bridging unit to electrically connect the components with each other when assembling the cell phone, and both sides of the FPC are provided with holes as the means of plugging connection, and the electronic components (for example a switch unit, a sound receiver, a circuit main board or an audio device) of the cell phone are disposed on both front and back side of the FPC. This kind of method that arranges holes on both sides of the FPC needs more steps when processing, and causes the cost higher and higher. In addition, the arranging of the conventional FPC occupies more space in the cell phone, and thus it is not the best way to arrange the accommodation space in the cell phone to the man who wants to increase the inside space of the cell phone. According to the afore-described problems, the inventors of the present invention designed a flexible print circuit board bending method for connecting in a cell phone and a flexible print circuit board thereof, so as to solve the problems of the prior arts.

### SUMMARY

To solve the problems in the conventional arts, it is a primary object of the present invention to provide a flexible print circuit board bending method for connecting in a cell phone and a flexible print circuit board thereof.

To achieve the above object, a flexible print circuit board bending method for connecting in a cell phone according to the present invention comprises the following steps of: A. arranging a plurality of connecting points on one side of the flexible printed circuit board; B. bending the flexible printed circuit board to form the flexible printed circuit board as a L shape to decrease the space occupied by the flexible printed circuit board, and each connecting point is exposed to the outside for electrically connecting; and C. assembling the flexible printed circuit board into a smart phone, and connecting the connecting points correspondingly to a plurality of devices such as a switch unit, a sound receiver, a circuit main board or an audio device inside the smart phone, so as to electronically connect to each others.

Preferably, the flexible printed circuit board comprises a base section having a first connecting point, and the base section extends a first extending arm toward one side of the base section, the first extending arm is perpendicularly bended at one extending end and further extends to form a perpendicular extending arm, and a second connecting point is disposed on one extending end of the perpendicular extending arm, and the base section extends a second extending arm toward another side of the base section, a third connecting point is disposed on the second extending arm, and a connecting piece is extended from a lateral side of the third connecting point, a fourth connecting point is further disposed on the connecting piece.

Preferably, in the step B, a root section of the first extending arm is bended toward the a perpendicular side corresponding to the base section, and then the perpendicular extending arm is folded several times so as to face the second connecting point to the back side, and then the second extending arm is rolled correspondingly to the base section from the root section of the second extending arm so as to face the front side of the second extending arm to the back side, and lastly the connecting piece is stood by perpendicularly bending the connecting piece.

Preferably, in the step C, the stood connecting piece is corresponded to a top end of the smart phone, and the fourth connecting point is connected and fixed to the switch unit, and the third connecting point is correspondingly connected to the sound receiver, and the second connecting point is correspondingly connected to the circuit main board, and the first connecting point is correspondingly connected to audio device.

To achieve another object, a flexible print circuit board according to the present invention is disclosed, which comprises a base section having a first connecting point, and the base section extends a first extending arm toward one side of the base section, the first extending arm is perpendicularly bended at one extending end and further extends to form a perpendicular extending arm, and a second connecting point is disposed on one extending end of the perpendicular extending arm, and the base section extends a second extending arm toward another side of the base section, a third connecting point is disposed on the second extending arm, and a connecting piece is extended from a lateral side of the third connecting point, a fourth connecting point is further disposed on the connecting piece.

With the above arrangements, the flexible print circuit board bending method according to the present invention is designed to bend the FPC at several positions, and thus connect the components disposed on the front and back sides of the FPC. Therefore, the FPC could be provided with connecting points only on one side, and thus does decrease the manufacturing cost. In addition, after folding the FPC, the space occupied in the cell phone could be exactly decreased and could further thin and lighten the cell phone.

With these and other objects, advantages, and features of the invention that may become hereinafter apparent, the nature of the invention may be more clearly understood by reference to the detailed description of the invention, the embodiments and to the several drawings herein.

### BRIEF DESCRIPTION OF THE DRAWINGS

The exemplary embodiment(s) of the present invention will be understood more fully from the detailed description given below and from the accompanying drawings of various embodiments of the invention, which, however, should not be taken to limit the invention to the specific embodiments, but are for explanation and understanding only.

FIG. 1 illustrates a flow chart of bending a flexible print circuit board in a cell phone in accordance with the present invention;

FIG. 2 illustrates a schematic diagram of one embodiment of bending a flexible print circuit board in a cell phone in accordance with the present invention;

FIG. 3 illustrates a schematic diagram of another embodiment of bending a flexible print circuit board in a cell phone in accordance with the present invention; and

FIG. 4 illustrates a schematic diagram of still another embodiment of bending a flexible print circuit board in a cell phone in accordance with the present invention.

### DETAILED DESCRIPTION

Exemplary embodiments of the present invention are described herein in the context of an illuminating system and a method thereof.

Those of ordinary skilled in the art will realize that the following detailed description of the exemplary embodiment(s) is illustrative only and is not intended to be in any way limiting. Other embodiments will readily suggest themselves to such skilled persons having the benefit of this disclosure. Reference will now be made in detail to implementations of the exemplary embodiment(s) as illustrated in the accompanying drawings. The same reference indicators will be used throughout the drawings and the following detailed description to refer to the same or like parts.

In accordance with the embodiment(s) of the present invention, the components, process steps, and/or data structures described herein may be implemented using various types of operating systems, computing platforms, computer programs, and/or general purpose machines. In addition, those of ordinary skill in the art will recognize that devices of a less general purpose nature, such as hardwired devices, field programmable gate arrays (FPGAs), application specific integrated circuits (ASICs), or the like, may also be used without departing from the scope and spirit of the inventive concepts disclosed herein. Where a method comprising a series of process steps is implemented by a computer or a machine and those process steps can be stored as a series of instructions readable by the machine, they may be stored on a tangible medium such as a computer memory device (e.g., ROM (Read Only Memory), PROM (Programmable Read Only Memory), EEPROM (Electrically Erasable Programmable Read Only Memory), FLASH Memory, Jump Drive, and the like), magnetic storage medium (e.g., tape, magnetic disk drive, and the like), optical storage medium (e.g., CD-ROM, DVD-ROM, paper card and paper tape, and the like) and other known types of program memory.

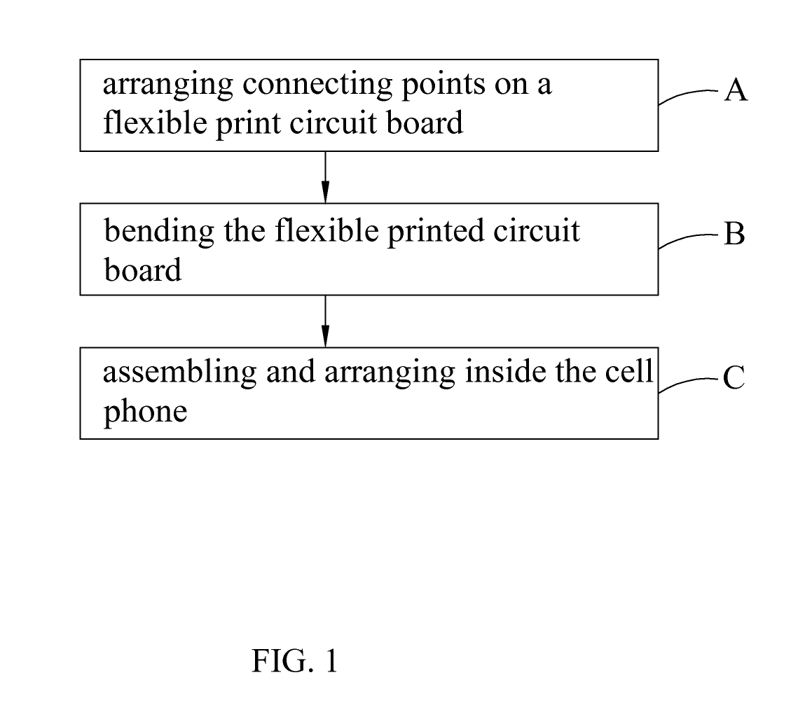

Please refer to FIG. 1, the present invention discloses a flexible print circuit board bending method for connecting in a cell phone, and in one preferred embodiment the present invention comprises the following steps of:

A. step of arranging connecting points on a flexible print circuit board;

B. step of bending the flexible printed circuit board; and

C. step of assembling and arranging inside the cell phone.

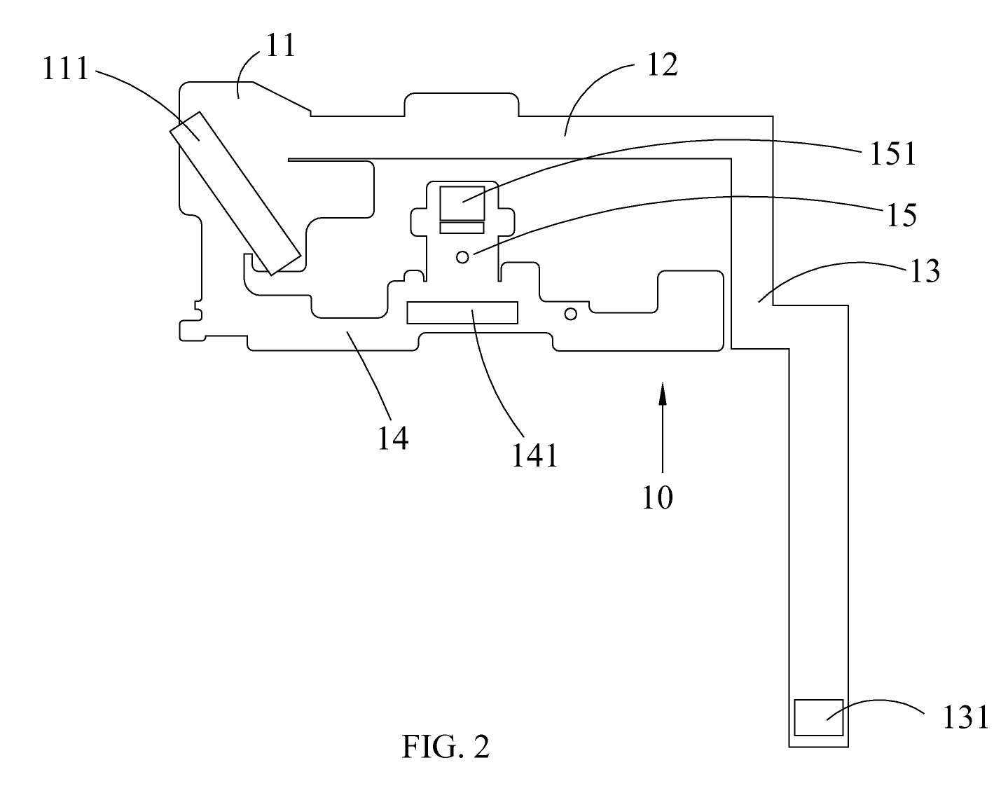

Please further refer to FIG. 2, in the afore-described step A, a plurality of connecting points is arranged on the front side of the flexible printed circuit board (FPC) 10. Prefeabaly, the flexible printed circuit board 10 comprises a base section 11 having a first connecting point 111, and the base section 11 extends a first extending arm 12 toward one side of the base section 11, the first extending arm 12 is perpendicularly bended at one extending end and further extends to form a perpendicular extending arm 13, and a second connecting point 131 is disposed on one extending end of the perpendicular extending arm 13, and the base section 11 extends a second extending arm 14 toward another side of the base section 11, a third connecting point 141 is disposed on the second extending arm 14, and a connecting piece 15 is extended from a lateral side of the third connecting point 141, a fourth connecting point 151 is further disposed on the connecting piece 15.

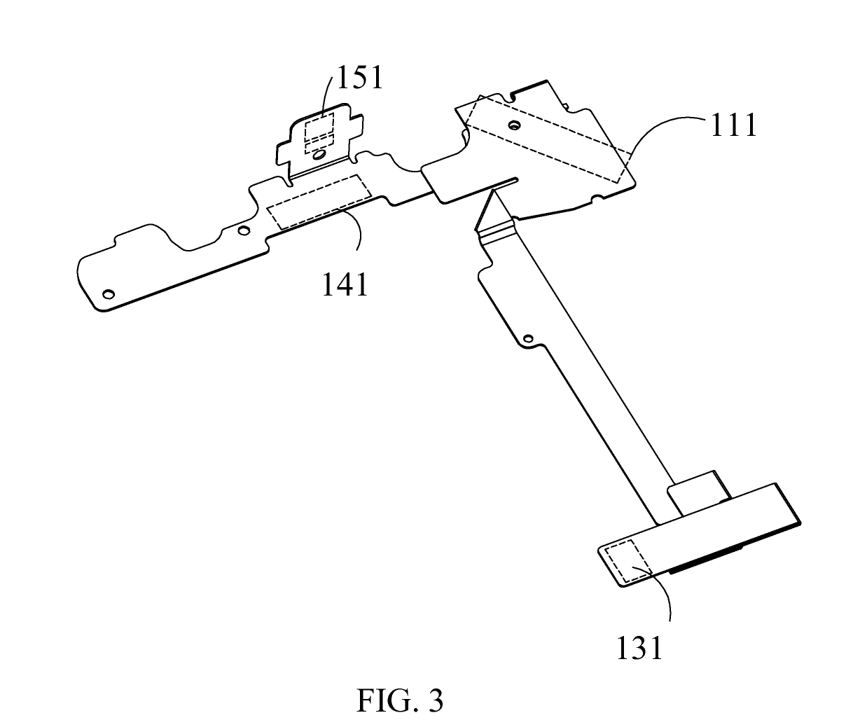

Please further refer to FIG. 3, in aforementioned step B, the flexible printed circuit board 10 is bended so as to further form the flexible printed circuit board 10 as an L shape to decrease the space occupied by the flexible printed circuit board 10, and each connecting point is exposed to the outside for electrically connecting. A root section of the first extending arm 12 is firstly bended toward the a perpendicular side corresponding to the base section 11, and then the perpendicular extending arm 13 is folded several times so as to face the second connecting point 131 to the back side, and then the second extending arm 14 is rolled correspondingly to the base section 11 from the root section of the second extending arm 14 so as to face the front side of the second extending arm 14 to the back side, and so the third connecting point 141, the connecting piece 15 and the fourth connecting point 151 are faced to the back side, and then lastly the connecting piece 15 is stood by perpendicularly bending it.

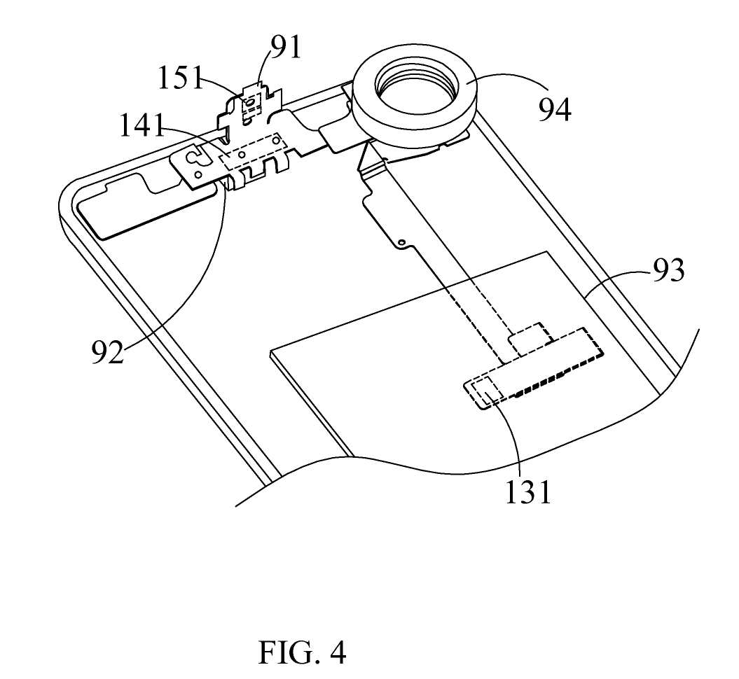

Please further refer to FIG. 4, in the step C, the flexible printed circuit board 10 is assembled into a smart phone 90, and the stood connecting piece 15 is corresponding to the top end of the smart phone 90, and the fourth connecting point 151 is connected and fixed with the switch unit 91, and the third connecting point 141 is correspondingly connected to the sound receiver 92, and the second connecting point 131 is correspondingly connected to the circuit main board 93, and the first connecting point 111 is correspondingly connected to audio device 94.

With the above arrangements, the flexible print circuit board bending method according to the present invention would bend the FPC 10 at several appropriate positions, and thus connect the components disposed on the front and back sides of the FPC 10 in the smart phone 90. In addition, because the FPC 10 could be provided with connecting points only on one side, the manufacturing cost could be effectively decreased. Besides, after folding the FPC 10, the space occupied in the smart phone 90 could be exactly decreased and could further thin and lighten the cell phone.

While particular embodiments of the present invention have been shown and described, it will be obvious to those skilled in the art that, based upon the teachings herein, changes and modifications may be made without departing from this invention and its broader aspects. Therefore, the appended claims are intended to encompass within their scope of all such changes and modifications as are within the true spirit and scope of the exemplary embodiment(s) of the present invention.

What is claimed is:

1. A method of bending a flexible printed circuit board for electrically connecting in a cell phone, the method comprising the following steps of:
A. arranging a plurality of connecting points on one side of the flexible printed circuit board;
B. bending the flexible printed circuit board to form the flexible printed circuit board as a L shape to decrease the space occupied by the flexible printed circuit board, and exposing each connecting point to the outside for electrically connecting; and
C. assembling the flexible printed circuit board into a smart phone, and connecting the connecting points correspondingly to a plurality of devices inside the smart phone, so as to electronically connect to each others.

2. The method of claim 1, wherein the devices comprises a switch unit, a sound receiver, a circuit main board and an audio device.

3. The method of claim 2, wherein the flexible printed circuit board comprises a base section having a first connecting point, and the base section extends a first extending arm toward one side of the base section, the first extending arm is perpendicularly bended at one extending end and further extends to form a perpendicular extending arm, and a second connecting point is disposed on one extending end of the perpendicular extending arm, and the base section extends a second extending arm toward another side of the base section, a third connecting point is disposed on the second extending arm, and a connecting piece is extended from a lateral side of the third connecting point, a fourth connecting point is further disposed on the connecting piece.

4. The method of claim 3, wherein in the step B, firstly a root section of the first extending arm is bended toward the a perpendicular side corresponding to the base section, and then the perpendicular extending arm is folded several times so as to face the second connecting point to the back side, and then the second extending arm is rolled correspondingly to the base section from the root section of the second extending arm so as to face the front side of the second extending arm to the back side, and lastly the connecting piece is stood by perpendicularly bending the connecting piece.

5. The method of claim 4, wherein in the step C, the stood connecting piece corresponds to a top end of the smart phone, and the fourth connecting point is connected and fixed to the switch unit, and the third connecting point is correspondingly connected to the sound receiver, and the second connecting point is correspondingly connected to the circuit main board, and the first connecting point is correspondingly connected to audio device.

6. A flexible printed circuit board used in a cell phone, comprising:
a base section having a first connecting point, and the base section extends a first extending arm toward one side of the base section, the first extending arm is perpendicularly bended at one extending end and further extends to form a perpendicular extending arm, and a second connecting point is disposed on one extending end of the perpendicular extending arm, and the base section extends a second extending arm toward another side of the base section, a third connecting point is disposed on the second extending arm, and a connecting piece is extended from a lateral side of the third connecting point, a fourth connecting point is further disposed on the connecting piece.
